(19) United States
(12) Patent Application Publication
(10) Pub. No.: US 2026/0293442 A1
(43) Pub. Date: Sep. 24, 2026

(54) DISPLAY SUBSTRATE AND METHOD FOR MANUFACTURING SAME, AND DISPLAY SCREEN

(71) Applicant: BOE Technology Group Co., Ltd., Beijing (CN)

(72) Inventor: Mingche HSIEH, Beijing (CN)

(21) Appl. No.: 19/476,116

(22) PCT Filed: Sep. 14, 2024
(86) PCT No.: PCT/CN2024/119128

§ 371 Date: Oct. 16, 2025

(30) Foreign Application Priority Data
Oct. 7, 2023 (CN) 202311286895.5

(51) Int. Cl. H10K 59/122; H10K 59/12; H10K 59/40; H10K 59/80

(52) U.S. Cl. CPC H10K 59/122; H10K 59/1201; H10K 59/40; H10K 59/879; H10K 59/8792

(57) ABSTRACT

Provided is display substrate. The display substrate includes a substrate, a pixel part, and a touch part; wherein the touch part includes a first isolation layer, a second isolation layer, and a first overcoat layer, and the second isolation layer is disposed on a side of the first isolation layer distal to the substrate; in the second-type pixel region, the first isolation layer is provided with a plurality of first spacing regions, the second isolation layer is provided with a plurality of second spacing regions, and the first spacing regions and the second spacing regions correspond to an orthographic projection of a pixel light-emitting region of the pixel part on the substrate; and the first overcoat layer is disposed on a side of the second isolation layer distal to the substrate, and the first spacing regions and the second spacing regions are filled with the first overcoat layer.

The present disclosure is a U.S. national stage of international application No. PCT/CN2024/119128, which claims priority to Chinese Patent Application No. 202311286895.5, filed on Oct. 7, 2023, and entitled “DISPLAY SUBSTRATE, METHOD FOR MANUFACTURING DISPLAY SUBSTRATE, AND DISPLAY SCREEN”, the disclosure of which is herein incorporated by reference in its entirety.

### TECHNICAL FIELD

The present disclosure relates to the field of display technologies, and in particular, relates to a display substrate and a method for manufacturing the same, and a display screen.

### BACKGROUND

With the continuous development of display technology, display screens are increasingly widely used. In some cases, when using electronic devices with display functions such as mobile phones or tablets, users hope to share the information displayed on the screen with others; however, in other cases, users desire privacy. For example, when handling confidential company information or entering personal information on a mobile phone, users want to reduce the risk of the information being seen by others. Therefore, the switch between display sharing and privacy has gradually become a functional trend.

### SUMMARY

The embodiments of the present disclosure provide a display substrate and a method for manufacturing the same, and a display screen. The technical solutions are as follows.

Some embodiments of the present disclosure provide a display substrate. The display substrate is provided with a first-type pixel region and a second-type pixel region, the first-type pixel region being a normal pixel region, and the second-type pixel region being a privacy pixel region.

The display substrate includes: a substrate, a pixel part, and a touch part, wherein the pixel part is disposed on the substrate, and the touch part is disposed on a side of the pixel part distal to the substrate;
wherein the touch part includes a first isolation layer, a second isolation layer, and a first overcoat layer, and the second isolation layer is disposed on a side of the first isolation layer distal to the substrate;
in the second-type pixel region, the first isolation layer is provided with multiple first spacing regions, the second isolation layer is provided with multiple second spacing regions, and the first spacing regions and the second spacing regions correspond to an orthographic projection of a pixel light-emitting region of the pixel part on the substrate; and
the first overcoat layer is disposed on a side of the second isolation layer distal to the substrate, and the first spacing regions and the second spacing regions are filled with the first overcoat layer;
wherein a third refractive index of the first overcoat layer is less than a first refractive index of the first isolation layer, and is less than a second refractive index of the second isolation layer.

In some embodiments, the first isolation layer is patterned into multiple first trapezoidal structures, the first spacing regions are between every two adjacent first trapezoidal structures, and an angle formed between the substrate and a lower base of each first trapezoidal structure proximal to the substrate ranges from 45 degrees to 75 degrees; and
the second isolation layer is patterned into multiple second trapezoidal structures, the second spacing regions are between every two adjacent second trapezoidal structures, and an angle formed between the substrate and a lower base of each second trapezoidal structure proximal to the substrate ranges from 45 degrees to 75 degrees,
wherein a length of an upper base of the first trapezoidal structure distal to the substrate is not less than a length of the lower base of the second trapezoidal structure proximal to the substrate.

In some embodiments, a ratio of the second refractive index to the third refractive index is greater than 1.10; and/or a ratio of the first refractive index to the third refractive index is greater than 1.10.

In some embodiments, the touch part further includes a buffer layer, a first metal layer, a second metal layer, an optical control layer, a black matrix layer, and a second overcoat layer, wherein
the buffer layer is disposed on a side of the pixel part distal to the substrate; the first isolation layer is disposed on a side of the buffer layer distal to the substrate; the first metal layer is disposed between the first isolation layer and the second isolation layer; the second metal layer is disposed between the second isolation layer and the first overcoat layer; the optical control layer is disposed on a side of the first overcoat layer distal to the substrate; and the black matrix layer is disposed on a side of the optical control layer distal to the substrate; and
the black matrix layer is provided with multiple third spacing regions, the third spacing regions correspond to the orthographic projection of the pixel light-emitting region of the pixel part on the substrate, the second overcoat layer is disposed on a side of the black matrix layer distal to the substrate, and the third spacing regions are filled with the second overcoat layer.

In some embodiments, in the second-type pixel region, the touch part further includes a third metal layer disposed between the first isolation layer and the buffer layer, a trace width of the third metal layer being greater than a trace width of the first metal layer, and being greater than a trace width of the second metal layer.

In some embodiments, the third metal layer is connected to a ground of the display substrate.

In some embodiments, normal pixels in the first-type pixel region and privacy pixels in the second-type pixel region are spaced apart from each other, and each sub-pixel in the privacy pixels includes multiple privacy pixel units.

In some embodiments, each sub-pixel in the display substrate includes multiple privacy pixel units and at least one normal pixel unit, a region where the privacy pixel units are located is the second-type pixel region, and a region where the at least one normal pixel unit is located is the first-type pixel region.

In some embodiments, a dimension of the privacy pixel unit does not exceed 15 um.

In some embodiments, the touch part further includes a first metal layer and a second metal layer, and the first metal layer and the second metal layer include multiple touch traces; and in an orthographic projection direction of the substrate, the touch traces are located in intervals between adjacent sub-pixels, and are located in intervals between adjacent privacy pixel units and normal pixel units.

In some embodiments, the pixel part includes an anode layer and a pixel definition layer, the anode layer includes multiple anode structures, and the pixel definition layer includes multiple pixel isolation structures; and
for any sub-pixel in the privacy pixels, the sub-pixel is divided into multiple privacy pixel units through the pixel isolation structures, and the privacy pixel units of the sub-pixel share one anode structure.

In some embodiments, the pixel part includes an anode layer and a pixel definition layer, the anode layer includes multiple anode structures, and the pixel definition layer includes multiple pixel isolation structures; and
for any sub-pixel in the privacy pixels, the sub-pixel is divided into multiple privacy pixel units through the pixel isolation structures, and the privacy pixel units of the sub-pixel are respectively connected to different anode structures.

In some embodiments, the touch part further includes a first metal layer and a second metal layer, and the first metal layer and the second metal layer include multiple touch traces; and in an orthographic projection direction of the substrate, the touch traces are located in intervals between adjacent sub-pixels.

In some embodiments, the pixel part includes an anode layer and a pixel definition layer, the anode layer includes multiple anode structures, and the pixel definition layer includes multiple pixel isolation structures; and
for any sub-pixel, the sub-pixel is divided into multiple privacy pixel units and one normal pixel unit through the pixel isolation structures, the normal pixel unit of the sub-pixel is connected to one anode structure, and the privacy pixel units of the sub-pixel share another anode structure.

In some embodiments, the pixel part includes an anode layer and a pixel definition layer, the anode layer includes multiple anode structures, and the pixel definition layer includes multiple pixel isolation structures; and
for any sub-pixel, the sub-pixel is divided into multiple privacy pixel units and one normal pixel unit through the pixel isolation structures, and the normal pixel unit and the privacy pixel units of the sub-pixel are respectively connected to different anode structures.

In some embodiments, the first isolation layer is a third overcoat layer, and the second isolation layer is a fourth overcoat layer.

In some embodiments, the first isolation layer is a first interlayer dielectric layer, and the second isolation layer is a second interlayer dielectric layer.

Some embodiments of the present disclosure provide a method for manufacturing a display substrate. The method includes:
forming a buffer layer on a side of a prefabricated panel distal to a substrate, wherein the prefabricated panel includes the substrate and a pixel part, and the pixel part is disposed on the substrate;
forming a first isolation layer on the buffer layer;
patterning the first isolation layer in a second-type pixel region to form multiple first spacing regions in the first isolation layer of the second-type pixel region, wherein the first spacing regions correspond to an orthographic projection of a pixel light-emitting region of the pixel part on the substrate;
forming a patterned first metal layer on the first isolation layer, and forming a second isolation layer on the first isolation layer and the first metal layer;
patterning the second isolation layer in the second-type pixel region to form multiple second spacing regions in the second isolation layer of the second-type pixel region, wherein the second spacing regions correspond to the orthographic projection of the pixel light-emitting region of the pixel part on the substrate;
forming a patterned second metal layer on the second isolation layer, and forming a first overcoat layer on the second isolation layer and the second metal layer, wherein the first spacing regions and the second spacing regions are filled with the first overcoat layer, a third refractive index of the first overcoat layer is less than a first refractive index of the first isolation layer, and is less than a second refractive index of the second isolation layer; and
forming a subsequent manufacturing process of the display substrate.

In some embodiments, before forming the first isolation layer on the buffer layer, the method further includes:
depositing a third metal layer on the buffer layer, and performing trace etching on the third metal layer to obtain a patterned first metal layer,
wherein a trace width of the third metal layer is greater than a trace width of the first metal layer, and is greater than a trace width of the second metal layer.

Some embodiments of the present disclosure provide a display screen. The display screen includes: a power supply assembly, and the display substrate as defined in the above embodiments, wherein
the power supply assembly is connected to the display substrate and is configured to supply power to the display substrate.

### BRIEF DESCRIPTION OF DRAWINGS

For a clearer illustration of the technical solutions in embodiments of the present disclosure or in the prior art, the accompanying drawings required to be used in the description of the embodiments or the prior art are briefly introduced below. It is apparent that the accompanying drawings in the description below are only for some embodiments of the present disclosure, and for those of ordinary skill in the art, other embodiments can be acquired based on the accompanying drawings.

FIG. 1 is a schematic diagram of a partial structure of a display substrate in the related art;

FIG. 2 is a schematic diagram of a privacy display screen with a cutting design according to some embodiments of the present disclosure;

FIG. 3 is a schematic diagram of a privacy display screen with a partition design according to some embodiments of the present disclosure;

FIG. 4 is a schematic cross-sectional diagram of a first type of display substrate according to some embodiments of the present disclosure;

FIG. 5 is a schematic cross-sectional diagram of a second type of display substrate according to some embodiments of the present disclosure;

FIG. 6 is a schematic cross-sectional diagram of a third type of display substrate according to some embodiments of the present disclosure;

FIG. 7a is a schematic cross-sectional diagram of a fourth type of display substrate according to some embodiments of the present disclosure;

FIG. 7b is a schematic cross-sectional diagram of a fifth type of display substrate according to some embodiments of the present disclosure;

FIG. 8 is a schematic diagram of a first type of privacy display screen with a partition design according to some embodiments of the present disclosure;

FIG. 9 is a schematic diagram of a second type of privacy display screen with a partition design according to some embodiments of the present disclosure;

FIG. 10 is a schematic cross-sectional diagram of a sixth type of display substrate according to some embodiments of the present disclosure;

FIG. 11 is a schematic cross-sectional diagram of a seventh type of display substrate according to some embodiments of the present disclosure;

FIG. 12 is a schematic diagram of a first type of privacy display screen with a cutting design according to some embodiments of the present disclosure;

FIG. 13 is a schematic diagram of a second type of privacy display screen with a cutting design according to some embodiments of the present disclosure;

FIG. 14 is a schematic diagram of a first type of pixel circuit according to some embodiments of the present disclosure;

FIG. 15 is a schematic diagram of a second type of pixel circuit according to some embodiments of the present disclosure;

FIG. 16a is a timing diagram of the pixel circuit illustrated in FIG. 14 in a privacy mode according to some embodiments of the present disclosure;

FIG. 16b is a timing diagram of the pixel circuit illustrated in FIG. 14 in a sharing mode according to some embodiments of the present disclosure;

FIG. 17a is a timing diagram of the pixel circuit illustrated in FIG. 15 in a privacy mode according to some embodiments of the present disclosure;

FIG. 17b is a first type of timing diagram of the pixel circuit illustrated in FIG. 15 in a sharing mode according to some embodiments of the present disclosure;

FIG. 17c is a second type of timing diagram of the pixel circuit illustrated in FIG. 15 in a sharing mode according to some embodiments of the present disclosure;

FIG. 18 is a schematic cross-sectional diagram of a display substrate in a method for manufacturing a display substrate according to some embodiments of the present disclosure;

FIG. 19 is a second schematic cross-sectional diagram of a display substrate in a method for manufacturing a display substrate according to some embodiments of the present disclosure;

FIG. 20 is a third schematic cross-sectional diagram of a display substrate in a method for manufacturing a display substrate according to some embodiments of the present disclosure;

FIG. 21 is a fourth schematic cross-sectional diagram of a display substrate in a method for manufacturing a display substrate according to some embodiments of the present disclosure;

FIG. 22 is a fifth schematic cross-sectional diagram of a display substrate in a method for manufacturing a display substrate according to some embodiments of the present disclosure;

FIG. 23 is a sixth schematic cross-sectional diagram of a display substrate in a method for manufacturing a display substrate according to some embodiments of the present disclosure;

FIG. 24 is a seventh schematic cross-sectional diagram of a display substrate in a method for manufacturing a display substrate according to some embodiments of the present disclosure;

FIG. 25 is an eighth schematic cross-sectional diagram of a display substrate in a method for manufacturing a display substrate according to some embodiments of the present disclosure; and

FIG. 26 is a ninth schematic cross-sectional diagram of a display substrate in a method for manufacturing a display substrate according to some embodiments of the present disclosure.

### DETAILED DESCRIPTION

The technical solutions in embodiments of the present disclosure will be clearly and fully described hereinafter with reference to the accompanying drawings in the embodiments of the present disclosure, and it is apparent that the described embodiments are only a portion, but not all of the embodiments of the present disclosure. Based on the embodiments in the present disclosure, all other embodiments acquired by those of ordinary skill in the art based on the present disclosure shall fall within the protection scope of the present disclosure.

In the related art, to realize the switchable function between privacy protection and sharing of the display screen, the entire pixel area is divided into a privacy pixel region and a normal pixel region. The emergent light angle of the normal pixel region (referring to the angle relative to the vertical direction of the display screen) is relatively large, such that the emergent light is observed from both the side and the front of the display screen. In contrast, the emergent light angle of the privacy pixel region is very small, and the emitted light is only observed from the front of the display screen. In the privacy mode, only the pixels in the privacy pixel region are lit, and the emergent light cannot be observed from the side of the display screen, thereby realizing the privacy protection function. However, how to achieve the small-angle emergent light of the privacy pixel region has become an urgent problem to be solved.

In the related art, to achieve small-angle emergent light in a privacy pixel region, multiple black matrix (BM) layers are generally employed in the display substrate as a privacy design, and the BM layers are arranged at varying height positions to shield the light rays from different angles.

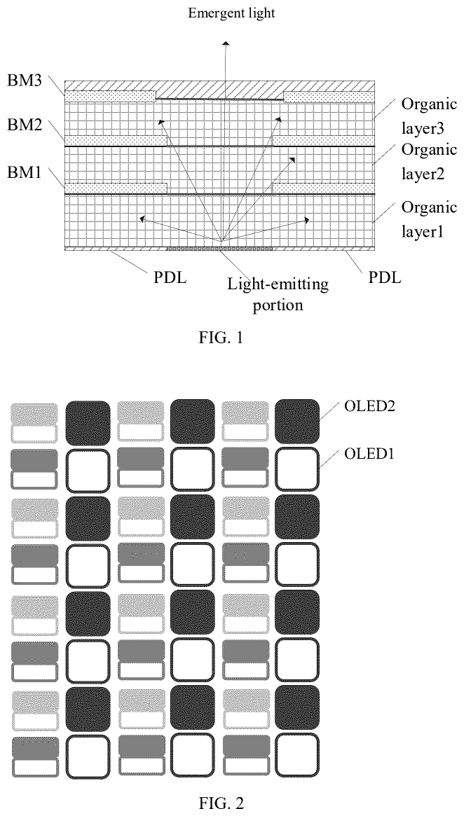

For example, referring to FIG. 1, on the light-emergent side of the display substrate, three BM layers and three organic layers are disposed to shield the emergent light with a large angle. However, this requires multiple BM and organic layers, which increases the thickness of the display substrate, easily leading to peeling issues between different film layers. FIG. 1 further illustrates a pixel definition layer (PDL) included in the display substrate. In addition, in FIG. 1, the three BM layers are respectively labeled as BM1, BM2, and BM3, and the three organic layers are respectively labeled as Organic layer1, Organic layer2, and Organic layer3. It should be understood that the structure of a touch part is not illustrated in FIG. 1, and the touch part may be disposed between the PDL and the Organic layer1.

To achieve the switching between the privacy and sharing modes of the display screen, the embodiments of the present disclosure provide two different display substrate designs,

One is a cutting design. That is, each sub-pixel is cut into a privacy pixel region and a normal pixel region, as illustrated in FIG. 2.

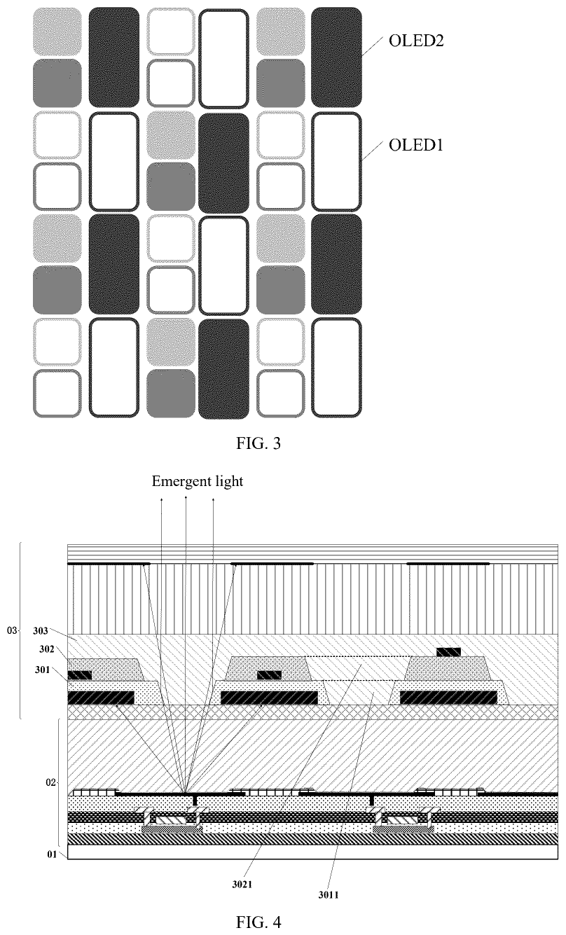

The other is a partition design. That is, pixels are directly divided into privacy pixels (a region where the privacy pixels are located is referred to as a privacy pixel region) and normal pixels (a region where the normal pixels are located is referred to as a normal pixel region), as illustrated in FIG. 3.

Taking an organic light-emitting diode (OLED) display screen as an example, in the two designs illustrated in FIGS. 2 and 3, the original OLED is divided into OLED1 (privacy) and OLED2 (normal). The angle of emergent light from the OLED2 is relatively large (with respect to the vertical direction of the display screen), such that the emergent light is observed from both the side surface and the front surface of the display screen, while the angle of the emergent light from the OLED1 is very small, such that the emergent light is only observed from the front surface of the display screen. Therefore, in the sharing mode, both the OLED1 and the OLED2 are on, or only the OLED2 is on, such that the emergent light can be observed from the side surface of the display screen. In the privacy mode, only the OLED1 is on, such that the emergent light cannot be observed from the side surface of the display screen, thereby achieving the privacy function.

Firstly, the embodiments of the present disclosure provide a display substrate. The display substrate is provided with a first-type pixel region and a second-type pixel region. Referring to FIG. 4, the display substrate includes: a substrate 01, a pixel part 02, and a touch part 03. The pixel part 02 is disposed on the substrate 01, and the touch part 03 is disposed on a side of the pixel part 02 distal to the substrate 01.

The touch part 03 includes a first isolation layer 301, a second isolation layer 302, and a first overcoat (OC) layer 303. Correspondingly, the first overcoat layer 303 may also be referred to as an OC1, and the second isolation layer 302 is disposed on a side of the first isolation layer 301 distal to the substrate 01.

In the second-type pixel region, the first isolation layer 301 is provided with multiple first spacing regions 3011, and the second isolation layer 302 is provided with multiple second spacing regions 3021. The first spacing regions 3011 and the second spacing regions 3021 correspond to the orthographic projection of the pixel light-emitting region of the pixel part 02 on the substrate 01.

The first overcoat layer 303 is disposed on a side of the second isolation layer 302 distal to the substrate 01, and the first spacing regions 3011 and the second spacing regions 3021 are filled with the first overcoat layer 303.

The third refractive index of the first overcoat layer 303 is less than the first refractive index of the first isolation layer 301, and the third refractive index of the first overcoat layer 303 is less than the second refractive index of the second isolation layer 302.

In some embodiments, the overcoat layer is a photosensitive resin film, and is generally made of an organic material. For example, the overcoat layer is made of a polyimide resin or acrylic resin material. The substrate 01 is made of glass or a flexible material. The flexible material is, for example, polyimide (PI). Correspondingly, the substrate 01 is also referred to as PI.

The first-type pixel region is the normal pixel region described above, and the second-type pixel region is the privacy pixel region described above. The first spacing region 3011 and the second spacing region 3021 corresponding to the orthographic projection of the pixel light-emitting region of the pixel part 02 on the substrate 01 may mean that the orthographic projections of the first spacing region 3011, the second spacing region 3021, and the pixel light-emitting region of the pixel part 02 on the substrate 01 have an overlapping portion, or the centers of the orthographic projections of the first spacing region, the second spacing region, and the pixel light-emitting region of the pixel part overlap on the substrate 01 (the distance between the centers is less than a preset distance value). In some embodiments, the orthographic projection of the pixel light-emitting region of the pixel part 02 on the substrate 01 is referred to as a third projection, the orthographic projection of the first spacing region 3011 on the substrate 01 is referred to as a first projection, and the orthographic projection of the second spacing region 3021 on the substrate 01 is referred to as a second projection. The first projection is disposed in the second projection, and the second projection is disposed in the third projection.

It should be understood that dashed lines in FIG. 4 are merely used to conveniently illustrate the first spacing region 3011 and the second spacing region 3021, and do not represent any actual structure.

In the embodiments of the present disclosure, the first overcoat layer 303 is filled in the first spacing region 3011 and the second spacing region 3021, the third refractive index of the first overcoat layer 303 is less than the first refractive index of the first isolation layer 301, and the third refractive index of the first overcoat layer 303 is less than the second refraction of the second isolation layer 302. In this way, in the case that the emergent light is incident on the side surfaces of the first isolation layer 301 and the second isolation layer 302 through the first overcoat layer 303, due to the increase in the refractive index, the light ray with a larger incident angle on the side surfaces of the first isolation layer 301 and the second isolation layer 302 is totally reflected. That is, for the display substrate, the emergent light with a larger angle is totally reflected on the side surfaces of the first isolation layer 301 and the second isolation layer 302, such that the angle between the reflected emergent light and the vertical direction of the display substrate becomes smaller, thereby achieving the small-angle light emission in the second-type pixel region. In addition, since the small-angle emergent light increases, the luminance of the small-angle emergent light can also be increased.

In some embodiments, both the first isolation layer 301 and the second isolation layer 302 are patterned structures, and the first spacing region 3011 and the second spacing region 3021 are formed by processes such as etching.

In some embodiments, the first isolation layer 301 is patterned into multiple first trapezoidal structures, and the first spacing regions 3011 are between every two adjacent first trapezoidal structures. The angle formed between the substrate 01 and the lower base of the first trapezoidal structure proximal to the substrate 01 ranges from 45 degrees to 75 degrees.

The second isolation layer 302 is patterned into multiple second trapezoidal structures, and the second spacing regions 3021 are between every two adjacent second trapezoidal structures. The angle formed between the substrate 01 and the lower base of the second trapezoidal structure proximal to the substrate 01 ranges from 45 degrees to 75 degrees.

In some embodiments, the length of the upper base of the first trapezoidal structure distal to the substrate 01 is not less than the length of the lower base of the second trapezoidal structure proximal to the substrate 01. Alternatively, the area of the orthographic projection of the first trapezoidal structure on the substrate 01 is less than the area of the orthographic projection of the second trapezoidal structure on the substrate 01.

It should be understood that the etched portion of the first isolation layer 301 is referred to as the first spacing region 3011, and the remaining portion is referred to as the first trapezoidal structure. The etched portion of the second isolation layer 302 is referred to as the second spacing region 3021, and the remaining portion is referred to as the second trapezoidal structure. The length of the lower base of the first trapezoidal structure is greater than the length of the upper base of the first trapezoidal structure, the length of the lower base of the second trapezoidal structure is greater than the length of the upper base of the first trapezoidal structure, and the length of the upper base of the first trapezoidal structure is not less than the length of the lower base of the second trapezoidal structure, thereby facilitating the arrangement of the second trapezoidal structure on the first trapezoidal structure. The lower base angles of the first trapezoidal structure and the second trapezoidal structure may range from 45 degrees to 75 degrees.

In the embodiments of the present disclosure, by setting the lower base angles of the first trapezoidal structure and the second trapezoidal structure within a range of 45 degrees to 75 degrees, the angle of the emergent light from the second-type pixel region (with respect to the vertical direction of the display substrate) is reduced, and the amount of the emergent light is increased, thereby increasing the luminance of the screen. In some other embodiments, the first trapezoidal structure and the second trapezoidal structure are in rectangular, pentagonal, or other shapes, all of which fall within the protection scope of the embodiments of the present disclosure.

In some embodiments, to achieve as much total reflection of the light ray as possible, certain requirements are posed on the refractive index. In some embodiments, the ratio of the second refractive index to the third refractive index is greater than 1.10; and/or the ratio of the first refractive index to the third refractive index is greater than 1.10.

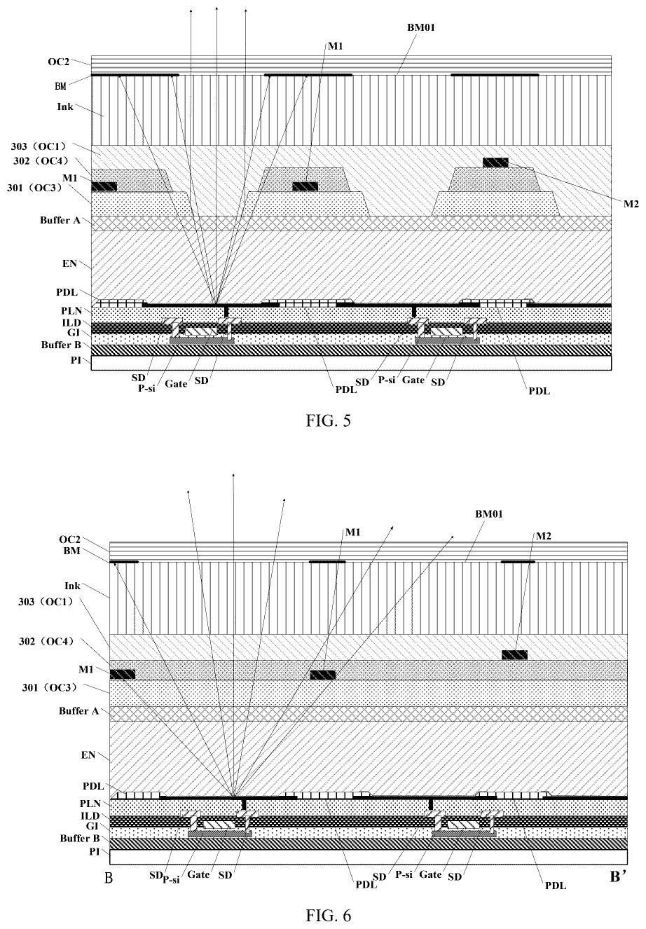

In some embodiments, referring to FIG. 5, the touch part 03 further includes a buffer layer, i.e., buffer layer A (Buffer A), a first metal layer (M1), a second metal layer (M2), an optical control layer (Ink), a black matrix (BM) layer, and a second overcoat layer (OC2).

The buffer layer A is disposed on a side of the pixel part 02 distal to the substrate 01 (e.g., PI); the first isolation layer 301 is disposed on a side of the buffer layer A distal to the substrate 01; the first metal layer (M1) is disposed between the first isolation layer 301 and the second isolation layer 302; the second metal layer (M2) is disposed between the second isolation layer 302 and the first overcoat layer 303 (OC1); the optical control layer is disposed on a side of the first overcoat layer 303 (OC1) distal to the substrate 01; and the black matrix layer (BM) is disposed on a side of the optical control layer (Ink) distal to the substrate 01.

The black matrix layer (BM) is provided with multiple third spacing regions BM01. The third spacing regions BM01 correspond to the orthographic projection of the pixel light-emitting region of the pixel part 02 on the substrate 01. The second overcoat layer (OC2) is disposed on a side of the black matrix layer (BM) distal to the substrate 01, and the third spacing regions BM01 are filled with the second overcoat layer (OC2). The lengths of the first spacing region 3011, the second spacing region 3021, and the third spacing region BM01 may be customized based on the actual situation.

In some embodiments, to ensure that the second isolation layer 302 is stably disposed on the first isolation layer 301, the length of the second trapezoidal structure needs to be less than the length of the first trapezoidal structure; that is, the length of the first spacing region 3011 is less than the length of the second spacing region 3021. To achieve the small-angle light emission in the second-type pixel region, in some embodiments, the length of the third spacing region BM01 is equal to the length of the second spacing region 3021, and correspondingly, the length of the third spacing region BM01 is greater than the length of the first spacing region 3011.

In addition, FIG. 5 further schematically illustrates that the display substrate may further include: a buffer layer (Buffer B), a gate insulator (GI), an interlayer dielectric (ILD) layer, a planarization layer (PLN), a pixel definition layer PDL, and an encapsulation layer (EN) located between the substrate 01 and the Buffer A and sequentially stacked in a direction distal to the substrate 01. In addition, the display substrate includes a low-temperature polycrystalline silicon layer P—Si used as an active layer and located between the buffer layer Buffer B and the gate insulator GI, a gate layer Gate located between the gate insulator GI and the interlayer dielectric layer ILD, a source/drain layer SD located between the interlayer dielectric layer ILD and the planarization layer PLN, and an organic light-emitting layer located between the planarization layer PLN and the encapsulation layer EN. The organic light-emitting layer illustrated in the figure has an anode structure. The organic light-emitting layer is connected to the source/drain layer SD, and the source/drain layer SD is connected to the low-temperature polycrystalline silicon layer P—Si. That is, in FIG. 6, PLN represents the planarization layer, GI represents the insulator layer, SD represents the source/drain layer, Gate represents the gate layer, PDL represents the pixel definition layer, P—Si represents the low-temperature polycrystalline silicon layer, and EN represents the encapsulation layer.

In some embodiments, the structure of the first-type pixel region is as illustrated in FIG. 6, and the first isolation layer 301 and the second isolation layer 302 of the first-type pixel region do not require a patterned design. Compared with the second-type pixel region illustrated in FIG. 1 (the touch part is not illustrated in FIG. 1), the second-type pixel region according to the embodiments of the present disclosure reduces the number of BM layers, thereby reducing the thickness of the display substrate and thus reducing the risk of film layer peeling.

In some embodiments, the first isolation layer 301 and the second isolation layer 302 are also overcoat (OC) layers or interlayer dielectric (ILD) layers.

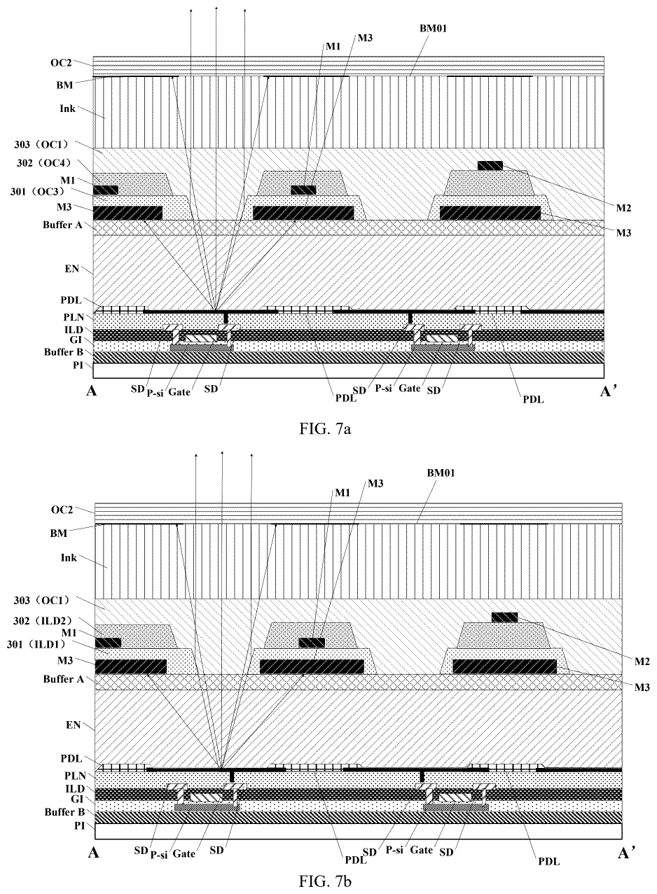

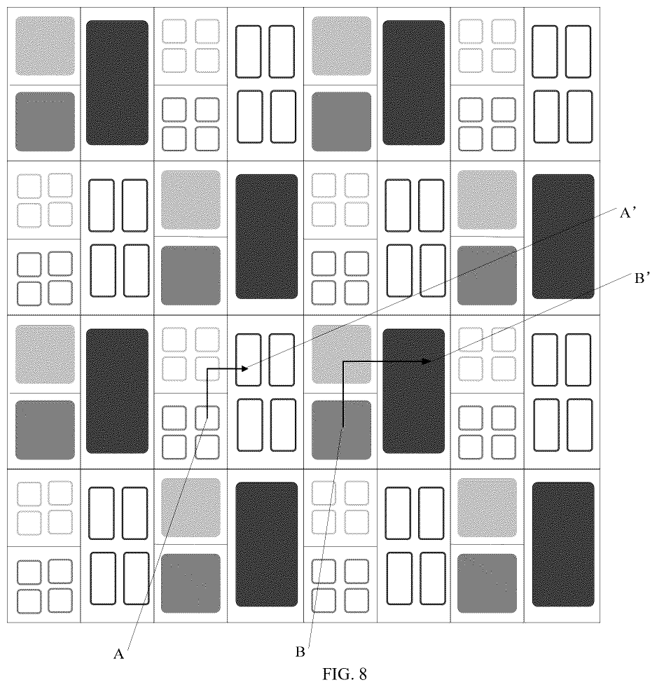

In some embodiments, for example, as illustrated in FIG. 7a, the first isolation layer 301 is a third overcoat layer (OC3), and the second isolation layer 302 is a fourth overcoat layer (OC4).

In some embodiments, for example, as illustrated in FIG. 7b, the first isolation layer 301 is a first interlayer dielectric layer (ILD1), and the second isolation layer 302 is a second interlayer dielectric layer (ILD2). In some embodiments, the interlayer dielectric layer is generally made of an inorganic material, for example, silicon nitride (SiN).

It should be understood that both FIGS. 5 and 6 are described by using an example in which the first isolation layer 301 is the third overcoat layer OC3 and the second isolation layer 302 is the fourth overcoat layer OC4.

In some embodiments, referring to FIG. 7a or 7b, the touch part 03 in the second-type pixel region further includes a third metal layer (M3); the third metal layer (M3) is disposed between the first isolation layer 301 (OC3) and the buffer layer (Buffer A), the trace width of the third metal layer (M3) is greater than the trace width of the first metal layer (M1), and the trace width of the third metal layer (M3) is greater than the trace width of the second metal layer (M2).

In some embodiments, the first metal layer (M1), the second metal layer (M2), and the third metal layer (M3) are all patterned into multiple traces.

The first metal layer (M1) and the second metal layer (M2) are a horizontal trace layer and a vertical trace layer of the touch trace, respectively, and are configured to achieve the touch function. By setting the trace width of the third metal layer (M3) to be greater than the trace width of the first metal layer (M1) and setting the trace width of the third metal layer (M3) to be greater than the trace width of the second metal layer (M2), the large-angle emergent light from the pixel light-emitting region of the pixel part 02 is shielded, thereby reducing the angle of the emergent light from the second-type pixel region.

In some embodiments, the third metal layer (M3) is connected to the ground of the display substrate. By connecting the trace of the third metal layer (M3) to the ground of the display substrate, the electrical signals of the touch part 03 and the pixel part 02 in the display substrate can be isolated, and the mutual interference of the electrical signals between the touch part 03 and the pixel part 02 is reduced, thereby improving the touch accuracy and the display accuracy.

In some embodiments, the first-type pixel region further includes the third metal layer (M3), so as to ensure that the normal pixels and the privacy pixels are relatively flat. Similarly, the third metal layer (M3) may be connected to the ground of the display substrate. In this way, the electrical signals of the touch part 03 and the pixel part 02 in the display substrate can also be isolated, and the mutual interference of the electrical signals between the touch part 03 and the pixel part 02 is reduced, thereby improving the touch accuracy and the display accuracy.

In some embodiments, the first-type pixel region further includes the third metal layer (M3). In the first-type pixel region, the trace width of the third metal layer (M3) is less than or equal to the trace width of the first metal layer (M1), and the trace width of the third metal layer (M3) is less than or equal to the trace width of the second metal layer (M2), thereby reducing the light-shielding effect of the third metal layer (M3).

In some embodiments, the display substrate according to the embodiments of the present disclosure adopts a partition design.

In some embodiments, referring to FIG. 8, the normal pixels in the first-type pixel region and the privacy pixels in the second-type pixel region are spaced apart from each other, and each sub-pixel in the privacy pixels includes multiple privacy pixel units.

A, A′ and B, B′ represent cross-sectional directions of the display substrate; that is, the hierarchical diagram of the display substrate according to the embodiments of the present disclosure is a cross-sectional diagram displayed in the direction of A, A′ or B, B′.

Different from the partition design in the prior art, the partition design according to the embodiments of the present disclosure further cuts the sub-pixels in the privacy pixel of the second-type pixel region. Each sub-pixel in the privacy pixels includes multiple privacy pixel units, thereby further reducing the dimension of the privacy pixel. In some embodiments, the dimension of the privacy pixel unit does not exceed 15 um. It should be understood that the dimension of the privacy pixel unit refers to the length of the longest line segment in the privacy pixel unit, for example, the diagonal line of a rectangle or the diameter of a circle.

In the embodiments of the present disclosure, each sub-pixel in the privacy pixel includes multiple privacy pixel units, thereby further reducing the dimension of the privacy pixel, and consequently reducing the angle of the emergent light from the second-type pixel region.

It should be understood that the layout of the traces (also referred to as touch traces, including touch electrodes) in the first metal layer (M1) and the second metal layer (M2) directly determines the touch sensitivity. Denser trace layout results in higher touch sensitivity.

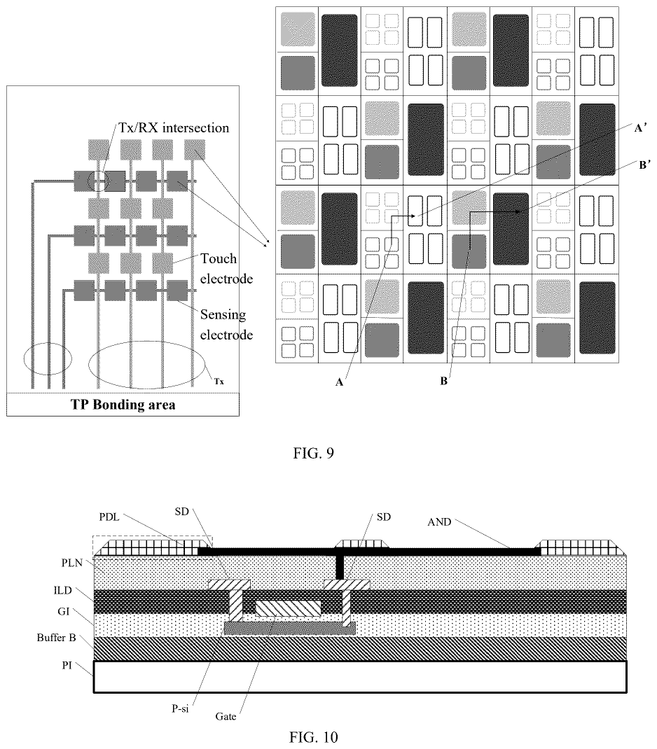

In some embodiments, referring to FIG. 9, the touch part 03 further includes a first metal layer (M1) and a second metal layer (M2), and both the first metal layer (M1) and the second metal layer (M2) include multiple touch traces. In addition, in the projection direction of the substrate 01, the touch traces may be located in intervals between adjacent sub-pixels, and may be located in intervals between adjacent privacy pixel units and normal pixel units. Tx represents transmission, RX represents reception, and TP Bonding area represents the touch electrode area.

It should be understood that the number of pixel units formed by cutting adjacent sub-pixels is the same or different, both of which fall within the protection scope of the embodiments of the present disclosure.

(1) In the partition design, the division of the sub-pixels in the privacy pixel is achieved by dividing a pixel definition layer (PDL).

In some embodiments, the pixel part 02 includes an anode layer (AND) and a pixel definition layer (PDL), and the anode layer (AND) includes multiple anode structures. Referring to FIG. 10, the pixel definition layer (PDL) includes multiple pixel isolation structures. On this basis, for any sub-pixel in the privacy pixel, the sub-pixel is divided into multiple privacy pixel units through the pixel isolation structure, and the privacy pixel units of the sub-pixel may share one anode structure. The pixel isolation structure is the structure within the dashed-line box in FIG. 10. It should be understood that the dashed-line box is only for the convenience of illustrating the anode structure, and does not represent an actual physical structure present in the display substrate.

(2) In the partition design, the division of the sub-pixels in the privacy pixel is achieved by dividing a pixel definition layer (PDL) and an anode layer (AND).

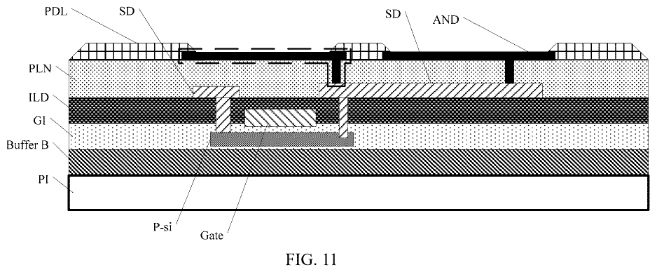

In some embodiments, the pixel part 02 includes an anode layer (AND) and a pixel definition layer (PDL). Referring to FIG. 11, the anode layer (AND) includes multiple anode structures, and the pixel definition layer (PDL) includes multiple pixel isolation structures. On this basis, for any sub-pixel in the privacy pixel, the sub-pixel is divided into multiple privacy pixel units through the pixel isolation structure, and the privacy pixel units of the sub-pixel are respectively connected to different anode structures. The anode structure is the structure within the dashed-line box in FIG. 11. It should be understood that the dashed-line box is only for the convenience of illustrating the anode structure, and does not represent an actual physical structure present in the display substrate.

In other embodiments, the display substrate according to the embodiments of the present disclosure adopts a cutting design.

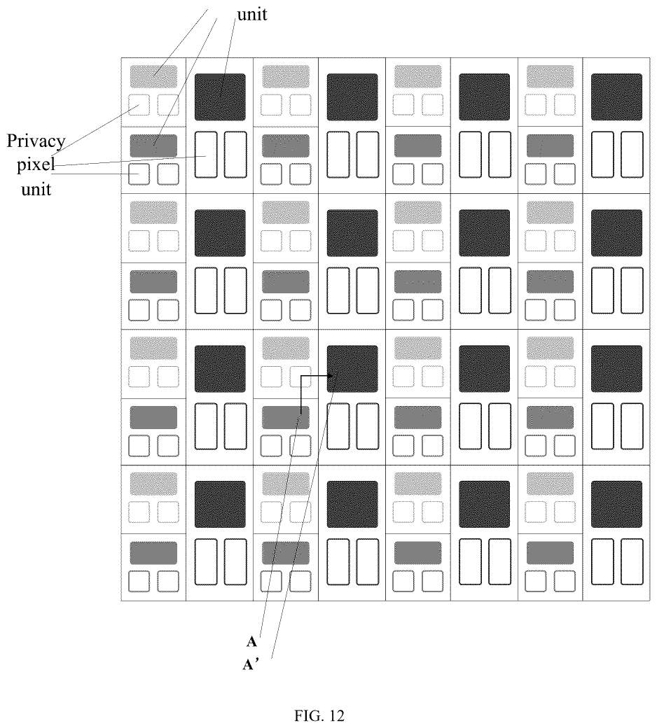

In some embodiments, referring to FIG. 12, each sub-pixel in the display substrate includes multiple privacy pixel units and at least one normal pixel unit. The region where the privacy pixel unit is located is the second-type pixel region, and the region where the normal pixel units are located is the first-type pixel region.

It should be understood that, different from dividing one sub-pixel into one privacy pixel unit and one normal pixel unit in the related art, in the embodiments of the present disclosure, one sub-pixel is divided into multiple privacy pixel units. For example, as illustrated in FIG. 12, one sub-pixel is divided into two privacy pixel units and one normal pixel unit. This can further reduce the dimension of the privacy pixel unit. In some embodiments, the dimension of the privacy pixel unit does not exceed 15 μm. It should be understood that the dimension of the privacy pixel unit refers to the length of the longest line segment in the privacy pixel unit, for example, the diagonal line of a rectangle or the diameter of a circle.

In the embodiments of the present disclosure, the sub-pixel includes multiple privacy pixel units, thereby further reducing the dimension of the privacy pixel, and consequently reducing the angle of the emergent light from the second-type pixel region.

It should be understood that the layout of the traces (also referred to as touch traces) in the first metal layer (M1) and the second metal layer (M2) directly determines the touch sensitivity. Denser trace layout results in higher touch sensitivity. In some embodiments, a horizontal touch trace and a vertical touch trace are respectively disposed in the first metal layer (M1) and the second metal layer (M2), thereby facilitating the layout of the touch traces. It should be understood that the touch trace may include a touch electrode structure.

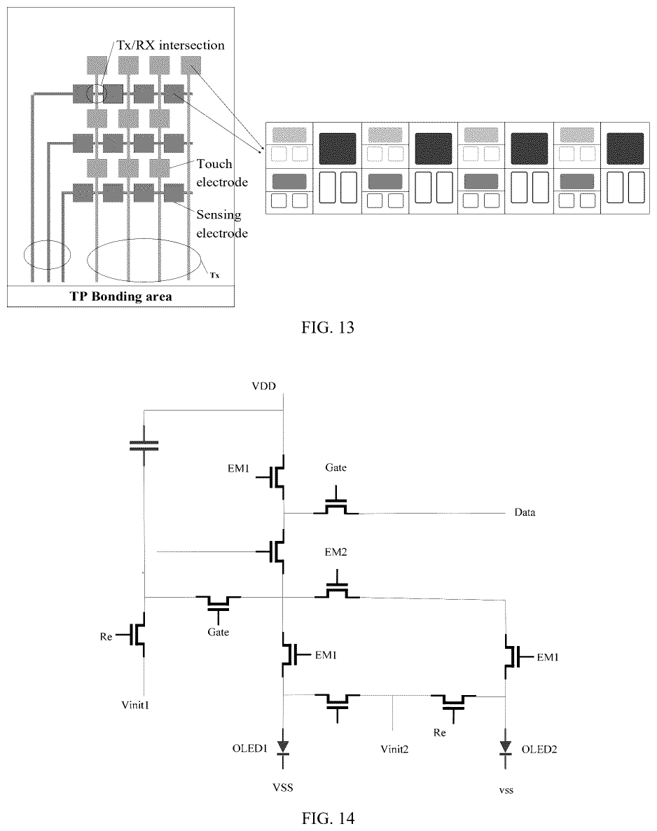

In some embodiments, referring to FIG. 13, the touch part 03 further includes a first metal layer (M1) and a second metal layer (M2), and both the first metal layer (M1) and the second metal layer (M2) include multiple touch traces. In addition, in the orthographic projection direction of the substrate 01, the touch traces are located in intervals between adjacent sub-pixels.

(1) In the cutting design, the division of the sub-pixels in the privacy pixel is achieved by dividing a pixel definition layer (PDL).

Still referring to FIG. 10, in some embodiments, the pixel part 02 includes an anode layer (AND) and a pixel definition layer (PDL). The anode layer (AND) includes multiple anode structures, and the pixel definition layer (PDL) includes multiple pixel isolation structures. On this basis, for any sub-pixel, the sub-pixel is divided into multiple privacy pixel units and one normal pixel unit through the pixel isolation structures, the normal pixel unit of the sub-pixel is connected to one anode structure, and the privacy pixel units of the sub-pixel share another anode structure.

(2) In the cutting design, the division of the sub-pixels in the privacy pixel is achieved by dividing a pixel definition layer and an anode layer.

Still referring to FIG. 11, the pixel part 02 includes an anode layer (AND) and a pixel definition layer (PDL). The anode layer (AND) includes multiple anode structures, and the pixel definition layer (PDL) includes multiple pixel isolation structures. On this basis, for any sub-pixel, the sub-pixel is divided into multiple privacy pixel units and one normal pixel unit through the pixel isolation structure, and the normal pixel unit and the privacy pixel units of the sub-pixel are respectively connected to different anode structures.

In some embodiments, the first-type pixel region and the second-type pixel region are achieved through one-to-one driving. That is, the first-type pixel region corresponds to one separate set of pixel circuits, and the second-type pixel region corresponds to another separate set of pixel circuits. In addition, one-to-two driving can also be achieved by adding a new scanning signal; that is, the first-type pixel region and the second-type pixel region can share one set of pixel circuits to achieve the switching between the privacy and sharing modes.

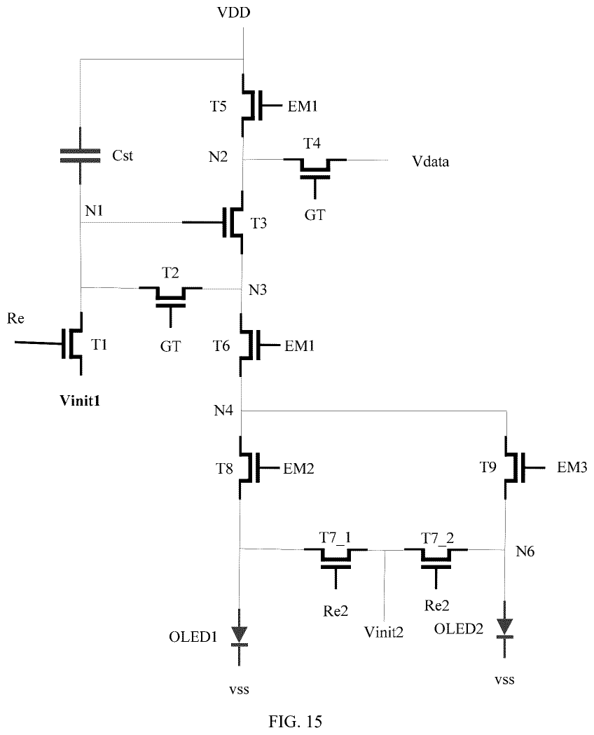

In some embodiments, the pixel circuit thereof is as illustrated in FIG. 14 or 15. Here, OLED1 represents a pixel/pixel unit of the second-type pixel region, and OLED2 represents a pixel/pixel unit of the first-type pixel region. VDD represents the positive electrode of the power supply voltage; VSS represents the negative electrode of the power supply voltage; EM1, EM2, EM3, Re, and GT (Gate) represent different timing signals; Data represents the data signal; Vinit1 represents the first initial voltage signal; Vinit2 represents the second initial voltage signal; T1 to T9 all represent transistors.

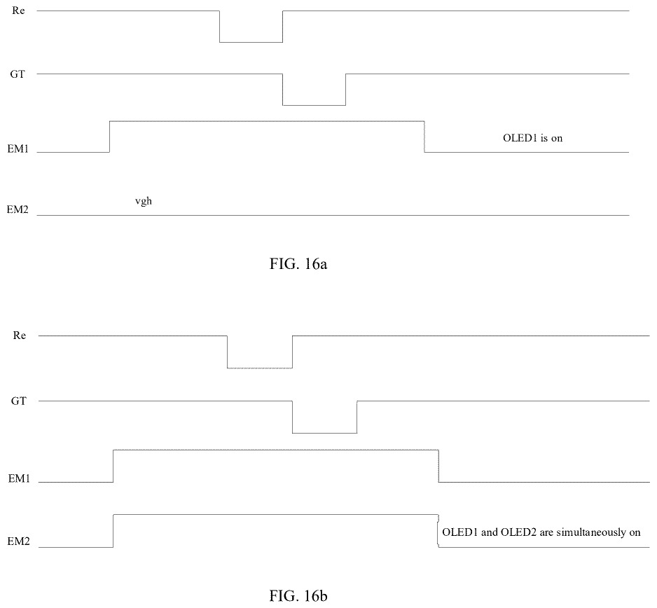

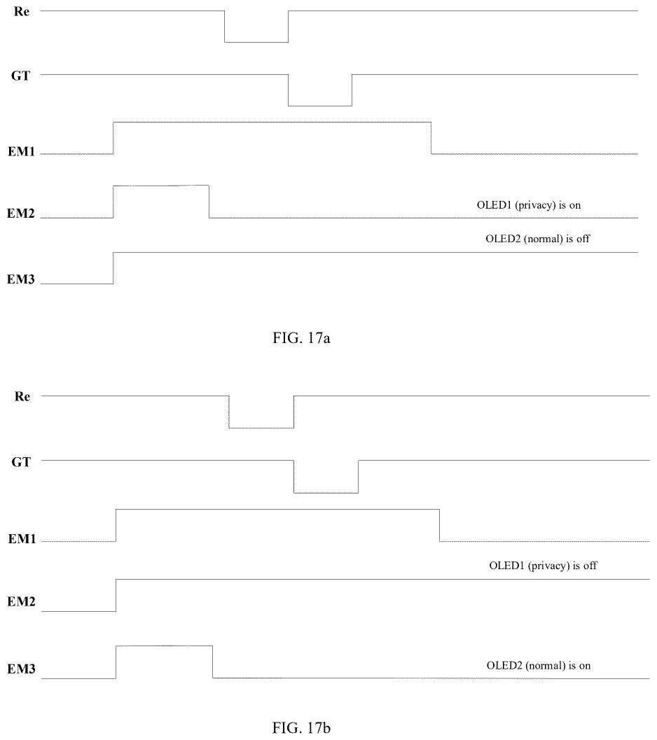

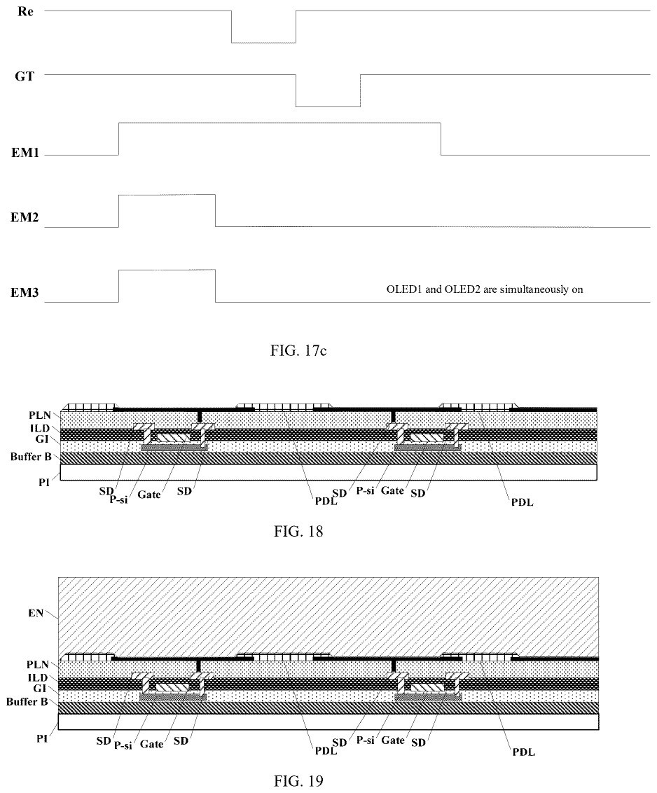

The timing diagrams of the pixel circuit illustrated in FIG. 14 in the privacy mode and the sharing mode are illustrated in FIGS. 16a and 16b, respectively, the timing diagram of the pixel circuit illustrated in FIG. 15 in the privacy mode is illustrated in FIG. 17a, and the timing diagram of the pixel circuit illustrated in FIG. 15 in the sharing mode is illustrated in FIG. 17b or 17c separately. Different from the pixel circuit illustrated in FIG. 14, the pixel circuit illustrated in FIG. 15 can achieve separate control of the OLED1 and the OLED2; that is, under the timing illustrated in FIG. 17b, the OLED1 is off while the OLED2 is on. The pixel circuit illustrated in FIG. 14 cannot achieve the function.

In summary, the embodiments of the present disclosure provide a display substrate. In the display substrate, the first overcoat layer is filled in the first spacing region and the second spacing region, and the third refractive index of the first overcoat layer is less than the first refractive index of the first isolation layer and is less than the second refraction of the second isolation layer. In this way, in the case that the emergent light ray is incident on the side surfaces of the first isolation layer and the second isolation layer through the first overcoat layer, due to the increase in the refractive index, the light ray with a larger incident angle on the side surfaces of the first isolation layer and the second isolation layer is totally reflected. That is, for the display substrate, the emergent light with a larger angle is totally reflected on the side surfaces of the first isolation layer and the second isolation layer, such that the angle between the reflected emergent light and the vertical direction of the display substrate becomes smaller, thereby achieving the small-angle light emission in the second-type pixel region. In addition, since the small-angle emergent light increases, the luminance of the small-angle emergent light can also be increased. Alternatively, implementing any product or method of the present disclosure does not necessarily require achieving all the advantages described above at the same time.

The embodiments of the present disclosure further provide a method for manufacturing a display substrate. The method is used for manufacturing the display substrate described above according to the embodiments of the present disclosure. The method includes the following steps.

In Step 1, a buffer layer A is formed on a side of a prefabricated panel distal to a substrate 01.

The prefabricated panel includes the substrate 01 and a pixel part 02, and the pixel part 02 is disposed on the substrate 01.

The prefabricated panel includes the substrate 01 and the pixel part 02. In some embodiments, the following are sequentially fabricated according to a fabrication process in the related art:
PI→Buffer B→P—Si→GI→Gate→ILD→SD→PLN→AND→PDL

Referring to FIG. 18, it can be seen that the substrate (PI) is fabricated first, and the substrate is made of glass or a flexible material. The flexible material includes the polyimide (PI) described above, or includes polyethylene naphthalate (PEN), polyethylene terephthalate (PET), or the like. The substrate made of flexible material is also referred to as a flexible substrate. In addition, the flexible substrate is of a single-layer structure or a multi-layer structure. In the case of a multi-layer structure, a buffer layer is added between the layers. The buffer layer is an inorganic thin film, which is a structure made of silicon nitride (SiNx), silicon oxide (SiOx), or a composite layer thereof on the substrate. Then, a buffer layer, namely a buffer layer B (Buffer B), a patterned active layer (P—Si), an insulator (GI), a gate layer (Gate), a source/drain electrode layer (SD), and a planarization layer (PLN), are formed on the substrate (PI). Next, an anode (AND) pattern, a pixel definition layer (PDL), a support pillar structure, a retaining wall structure, and the like are fabricated on the planarization layer (PLN). The materials of the pixel definition layer (PDL), the support pillar structure, and the retaining wall structure are the same as the material of the planarization layer (PLN). For example, all such materials are organic insulating materials, and are made of polyimide-based photoresist. The support pillar structure is mainly disposed in the active region AA, and the retaining wall structure is located in the non-active region. The retaining wall structure is formed by one or multiple layers of the planarization layer (PLN), the pixel definition layer (PDL), and the support pillar structure. Thereafter, an encapsulation layer (EN) and a buffer layer A (Buffer A) are sequentially formed on a side of the pixel definition layer (PDL) distal to the substrate 01.

In some embodiments, an organic light-emitting layer and a cathode layer are formed on the back plate using a vacuum evaporation process. The organic light-emitting layer includes, but is not limited to, a hole injection layer, a hole transport layer, a light-emitting layer, an electron transport layer, and the like, and a thin film encapsulation layer is prepared. The thin film encapsulation layer includes an inorganic thin film layer that blocks water and oxygen and an organic thin film layer that provides stress relief and planarization. The inorganic thin film layer is manufactured by chemical vapor deposition or atomic layer deposition, and the material is silicon nitride, silicon oxide, silicon oxynitride, aluminum oxide, titanium oxide, or the like, but is not limited thereto. The organic thin film layer is manufactured by using a method such as inkjet printing, screen printing, or dispensing.

In some embodiments, firstly, a first inorganic layer is deposited on the light-emitting device (i.e., the organic light-emitting layer), and the first inorganic layer is composed of one of the aforementioned materials, or a combination of multiple aforementioned materials that overlap with each other. The protection area of the first inorganic layer is larger than the display area of the active region AA. Generally, the vertical projection of the coverage area of the first inorganic layer is outside the retaining wall structure. Then, a first organic layer is manufactured on the first inorganic layer, the coverage area of the first organic layer is smaller than that of the first inorganic layer, and the vertical projection of the coverage area of the first organic layer is larger than that of the cathode layer. Next, a second inorganic layer is fabricated on the first organic layer. The fabrication method and material of the second inorganic layer are the same as those of the first inorganic layer, and the coverage area of the second inorganic layer is the same as or larger than that of the first inorganic layer. Similarly, the second inorganic layer is composed of a single inorganic material, or is a combination of multiple aforementioned inorganic layers (the first inorganic layer and the second inorganic layer are not illustrated in the figure). The finally formed prefabricated panel may be as illustrated in FIG. 19.

It should be understood that the prefabricated panel further includes an electro luminescent (EL) layer, a cathode layer, and the like, which are not illustrated in FIG. 19. The specific manufacturing methods for the EL layer, the cathode layer, and other layer structures may refer to the related art and are not specifically limited in the embodiments of the present disclosure.

In Step 2, a first isolation layer 301 is formed on the buffer layer A.

In some embodiments, the first isolation layer 301 is directly manufactured on the buffer layer A.

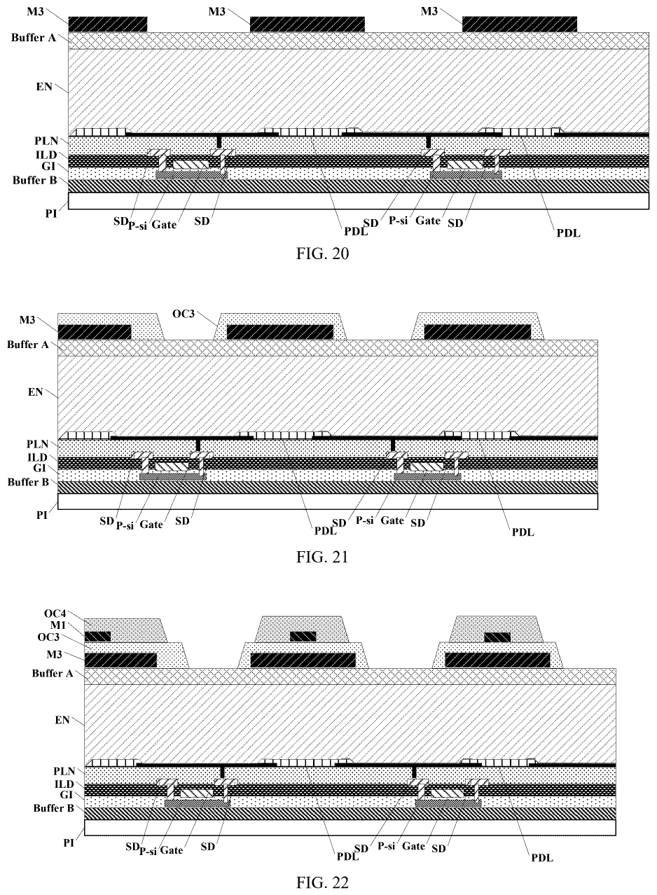

In some embodiments, referring to FIG. 20, the display substrate according to the embodiments of the present disclosure further includes a third metal layer (M3). In some embodiments, before manufacturing the first isolation layer 301 on the buffer layer A, the method further includes: depositing a third metal layer on the buffer layer A, and performing trace etching on the third metal layer to obtain a patterned third metal layer (M3).

After the buffer layer A, i.e., Buffer A (which may be made of SiNx), is manufactured on the encapsulation layer EN, the third metal layer M3 (which may be made of Ti/Ag/Ti) is deposited and etched to form an M3 pattern, and the M3 pattern is only present in the second-type pixel region, as illustrated in FIG. 20.

In Step 3, the first isolation layer 301 in a second-type pixel region is patterned to form multiple first spacing regions 3011 in the first isolation layer 301 of the second-type pixel region.

The first spacing region 3011 may correspond to the orthographic projection of the pixel light-emitting region of the pixel part 02 on the substrate 01.

A low-refraction (i.e., low refractive index) first isolation layer 301 (OC3) is applied and patterned to cover the M3 pattern and/or Buffer A. The refractive index of OC 3 is 1.4 to 1.55, for example, as illustrated in FIG. 21.

In Step 4, a patterned first metal layer is formed on the first isolation layer 301, and a second isolation layer 302 is formed on the first isolation layer 301 and the first metal layer.

The first metal layer M1 (which may be made of Ti/Ag/Ti) may be deposited and etched to form an M1 pattern, and the second isolation layer 302 (OC4) is applied. The refractive index of OC2 is 1.6 to 1.75, for example, as illustrated in FIG. 22.

In Step 5, the second isolation layer 302 in the second-type pixel region is patterned to form multiple second spacing regions 3021 in the second isolation layer 302 of the second-type pixel region.

The second spacing region 3021 may correspond to the orthographic projection of the pixel light-emitting region of the pixel part 02 on the substrate 01.

The applied OC4 is patterned, for example, as illustrated in FIG. 22.

In Step 6, a patterned second metal layer is formed on the second isolation layer 302, and a first overcoat layer 303 is manufactured on the second isolation layer 302 and the second metal layer.

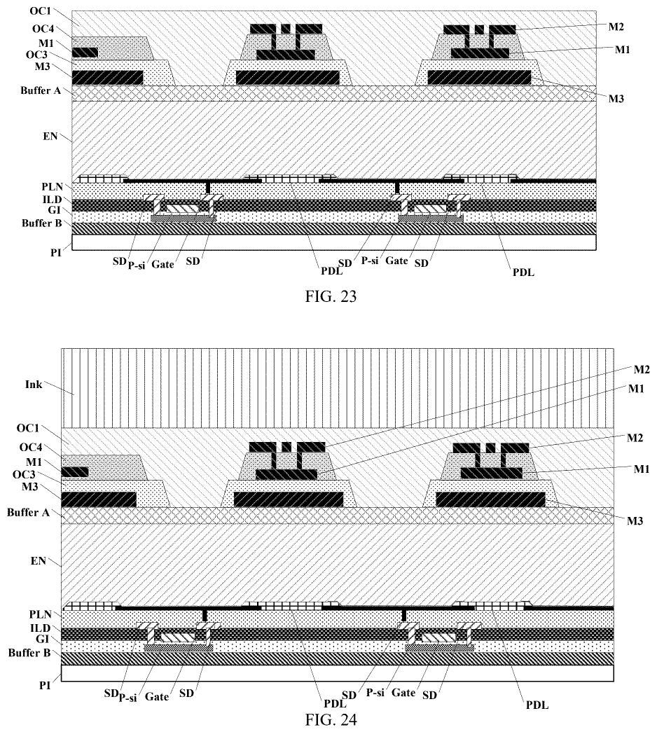

Referring to FIG. 23, the first spacing regions 3011 and the second spacing regions 3021 may be filled with the first overcoat layer 303. The third refractive index of the first overcoat layer 303 (OC1) is less than the first refractive index of the first isolation layer 301, and the third refractive index of the first overcoat layer 303 (OC1) is less than the second refractive index of the second isolation layer 302.

The second metal layer M2 (which may be made of Ti/Ag/Ti) is deposited and etched to form an M2 pattern, and the first overcoat layer 303 (OC1) is applied and patterned, for example, as illustrated in FIG. 23. The refractive index of OC3 may be 1.6 to 1.75.

In Step 7, a subsequent manufacturing process of the display substrate is performed.

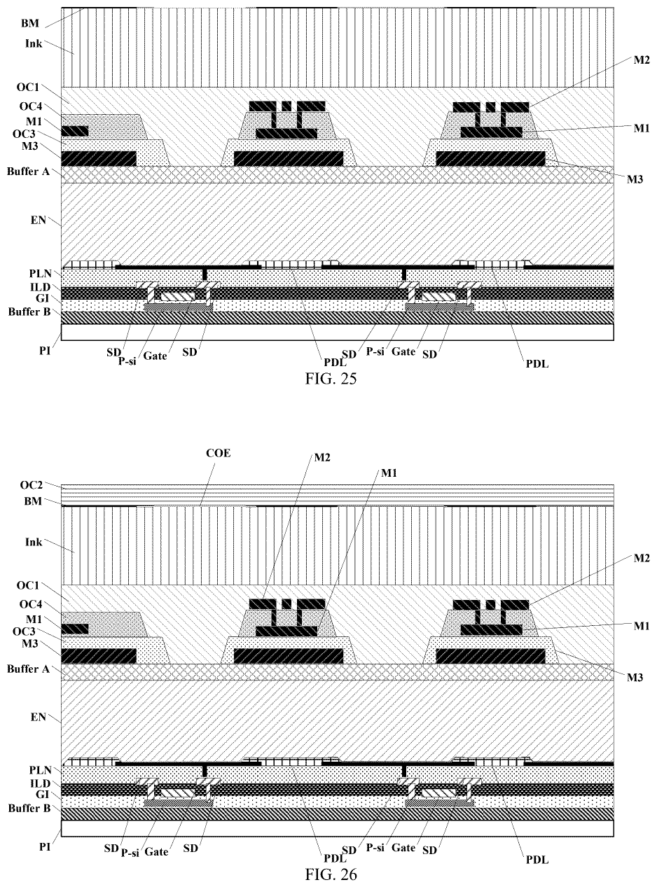

The subsequent manufacturing process of the display substrate may include: (1) An organic layer Ink with a high film thickness is applied, which may be performed by a multiple-blade coating method, a spin coating method, or a single inkjet method. The thickness of the Ink may be 8 um to 17 um, for example, as illustrated in FIG. 24. (2) A BM layer or a color filter on encapsulation (COE) is fabricated. In the case that a polarizer (POL) is not attached in the subsequent process, the color filter on encapsulation needs to be manufactured. For example, as illustrated in FIG. 25, taking the manufacturing of the color filter on encapsulation as an example, the width of the black matrix layer (BM) on the pixel definition layer (PDL) may be less than/equal to the width of the third metal layer (M3). (3) The application of the fourth overcoat layer OC4 is completed, as illustrated in FIG. 26.

It should be understood that since the method for manufacturing the display substrate achieves substantially the same technical effects as the aforementioned display substrate, for the purpose of brevity, the technical effects of the method for manufacturing the display substrate will not be repeated herein.

The embodiments of the present disclosure further provide a display screen. The display screen includes a power supply assembly and the display substrate according to any one of the embodiments of the present disclosure.

The power supply assembly is connected to the display substrate and is configured to supply power to the display substrate.

It should be understood that since the display screen achieves substantially the same technical effects as the aforementioned display substrate, for the purpose of brevity, the technical effects for the display screen will not be repeated herein.

It should be understood that the electro-luminescent layer, the cathode layer, and other common layers are not illustrated in the accompanying drawings of the embodiments of the present disclosure. The specific structures of the electro-luminescent layer, the cathode layer, and other common layers may refer to the related art and are not specifically limited in the embodiments of the present disclosure.

It should be understood that in the accompanying drawings of the embodiments of the present disclosure, the first isolation layer 301 being the OC3 layer and the second isolation layer 302 being the OC4 layer are merely taken as an example, and are not intended to limit the first isolation layer 301 and the second isolation layer 302 to the OC layers. For example, the case where the first isolation layer 301 is an ILD1 layer and the second isolation layer 302 is an ILD2 layer may fall within the protection scope of the embodiments of the present disclosure.

It should be noted that relational terms used herein, such as first and second, are merely used to distinguish one entity or operation from another entity or operation without necessarily requiring or implying any such actual relationship or order between such entities or operations. Moreover, the terms “include”, “including”, or any other variation thereof are intended to encompass a non-exclusive inclusion, such that a process, method, item, or device that includes a list of elements not only includes those elements, but also includes other elements not expressly listed or elements inherent to such process, method, item, or device. Without further limitation, an element defined by the phrase “including a . . . ” does not exclude the presence of additional identical elements in the process, method, item, or device that includes the element.

The foregoing shows only optional embodiments of the present disclosure and is not intended to limit the protection scope of the present disclosure. Any modifications, equivalent substitutions, improvements, and the like made within the principle of the present disclosure should fall within the protection scope of the present disclosure.

1. A display substrate, wherein the display substrate is provided with a first-type pixel region and a second-type pixel region, the first-type pixel region being a normal pixel region, and the second-type pixel region being a privacy pixel region; and the display substrate comprises:
a substrate, a pixel part, and a touch part, wherein the pixel part is disposed on the substrate, and the touch part is disposed on a side of the pixel part distal to the substrate;
wherein the touch part comprises a first isolation layer, a second isolation layer, and a first overcoat layer, and the second isolation layer is disposed on a side of the first isolation layer distal to the substrate;
in the second-type pixel region, the first isolation layer is provided with a plurality of first spacing regions, the second isolation layer is provided with a plurality of second spacing regions, and the first spacing regions and the second spacing regions correspond to an orthographic projection of a pixel light-emitting region of the pixel part on the substrate; and
the first overcoat layer is disposed on a side of the second isolation layer distal to the substrate, and the first spacing regions and the second spacing regions are filled with the first overcoat layer;
wherein a third refractive index of the first overcoat layer is less than a first refractive index of the first isolation layer, and is less than a second refractive index of the second isolation layer.

2. The display substrate according to claim 1, wherein the first isolation layer is patterned into a plurality of first trapezoidal structures, the first spacing regions are between every two adjacent first trapezoidal structures, and an angle formed between the substrate and a lower base of each first trapezoidal structure proximal to the substrate ranges from 45 degrees to 75 degrees; and
the second isolation layer is patterned into a plurality of second trapezoidal structures, the second spacing regions are between every two adjacent second trapezoidal structures, and an angle formed between the substrate and a lower base of each second trapezoidal structure proximal to the substrate ranges from 45 degrees to 75 degrees,
wherein a length of an upper base of the first trapezoidal structure distal to the substrate is not less than a length of the lower base of the second trapezoidal structure proximal to the substrate.

3. The display substrate according to claim 1, wherein a ratio of the second refractive index to the third refractive index is greater than 1.10; and/or a ratio of the first refractive index to the third refractive index is greater than 1.10.

4. The display substrate according to claim 1, wherein the touch part further comprises a buffer layer, a first metal layer, a second metal layer, an optical control layer, a black matrix layer, and a second overcoat layer, wherein
the buffer layer is disposed on a side of the pixel part distal to the substrate; the first isolation layer is disposed on a side of the buffer layer distal to the substrate; the first metal layer is disposed between the first isolation layer and the second isolation layer; the second metal layer is disposed between the second isolation layer and the first overcoat layer; the optical control layer is disposed on a side of the first overcoat layer distal to the substrate; and the black matrix layer is disposed on a side of the optical control layer distal to the substrate; and
the black matrix layer is provided with a plurality of third spacing regions, the third spacing regions correspond to the orthographic projection of the pixel light-emitting region of the pixel part on the substrate, the second overcoat layer is disposed on a side of the black matrix layer distal to the substrate, and the third spacing regions are filled with the second overcoat layer.

5. The display substrate according to claim 4, wherein in the second-type pixel region, the touch part further comprises a third metal layer disposed between the first isolation layer and the buffer layer, a trace width of the third metal layer being greater than a trace width of the first metal layer, and being greater than a trace width of the second metal layer.

6. The display substrate according to claim 5, wherein the third metal layer is connected to a ground of the display substrate.

7. The display substrate according to claim 1, wherein normal pixels in the first-type pixel region and privacy pixels in the second-type pixel region are spaced apart from each other, and each sub-pixel in the privacy pixels comprises a plurality of privacy pixel units.

8. The display substrate according to claim 1, wherein each sub-pixel in the display substrate comprises a plurality of privacy pixel units and at least one normal pixel unit, a region where the privacy pixel units are located is the second-type pixel region, and a region where the at least one normal pixel unit is located is the first-type pixel region.

9. The display substrate according to claim 7, wherein a dimension of the privacy pixel unit does not exceed 15 um.

10. The display substrate according to claim 7, wherein the touch part further comprises a first metal layer and a second metal layer, and the first metal layer and the second metal layer comprise a plurality of touch traces; and in an orthographic projection direction of the substrate, the touch traces are located in intervals between adjacent sub-pixels, and are located in intervals between adjacent privacy pixel units and normal pixel units.

11. The display substrate according to claim 7, wherein the pixel part comprises an anode layer and a pixel definition layer, the anode layer comprises a plurality of anode structures, and the pixel definition layer comprises a plurality of pixel isolation structures; and
for any sub-pixel in the privacy pixels, the sub-pixel is divided into a plurality of privacy pixel units through the pixel isolation structures, and the privacy pixel units of the sub-pixel share one anode structure.

12. The display substrate according to claim 7, wherein the pixel part comprises an anode layer and a pixel definition layer, the anode layer comprises a plurality of anode structures, and the pixel definition layer comprises a plurality of pixel isolation structures; and
for any sub-pixel in the privacy pixels, the sub-pixel is divided into a plurality of privacy pixel units through the pixel isolation structures, and the privacy pixel units of the sub-pixel are respectively connected to different anode structures.

13. The display substrate according to claim 8, wherein the touch part further comprises a first metal layer and a second metal layer, and the first metal layer and the second metal layer comprise a plurality of touch traces; and in an orthographic projection direction of the substrate, the touch traces are located in intervals between adjacent sub-pixels.

14. The display substrate according to claim 8, wherein the pixel part comprises an anode layer and a pixel definition layer, the anode layer comprises a plurality of anode structures, and the pixel definition layer comprises a plurality of pixel isolation structures; and
for any sub-pixel, the sub-pixel is divided into a plurality of privacy pixel units and one normal pixel unit through the pixel isolation structures, the normal pixel unit of the sub-pixel is connected to one anode structure, and the privacy pixel units of the sub-pixel share another anode structure.

15. The display substrate according to claim 8, wherein the pixel part comprises an anode layer and a pixel definition layer, the anode layer comprises a plurality of anode structures, and the pixel definition layer comprises a plurality of pixel isolation structures; and
for any sub-pixel, the sub-pixel is divided into a plurality of privacy pixel units and one normal pixel unit through the pixel isolation structures, and the normal pixel unit and the privacy pixel units of the sub-pixel are respectively connected to different anode structures.

16. The display substrate according to claim 1, wherein the first isolation layer is a third overcoat layer, and the second isolation layer is a fourth overcoat layer.

17. The display substrate according to claim 1, wherein the first isolation layer is a first interlayer dielectric layer, and the second isolation layer is a second interlayer dielectric layer.

18. A method for manufacturing a display substrate, comprising:
forming a buffer layer on a side of a prefabricated panel distal to a substrate, wherein the prefabricated panel comprises the substrate and a pixel part, and the pixel part is disposed on the substrate;
forming a first isolation layer on the buffer layer;
patterning the first isolation layer in a second-type pixel region to form a plurality of first spacing regions in the first isolation layer of the second-type pixel region, wherein the first spacing regions correspond to an orthographic projection of a pixel light-emitting region of the pixel part on the substrate;
forming a patterned first metal layer on the first isolation layer, and forming a second isolation layer on the first isolation layer and the first metal layer;
patterning the second isolation layer in the second-type pixel region to form a plurality of second spacing regions in the second isolation layer of the second-type pixel region, wherein the second spacing regions correspond to the orthographic projection of the pixel light-emitting region of the pixel part on the substrate;
forming a patterned second metal layer on the second isolation layer, and forming a first overcoat layer on the second isolation layer and the second metal layer, wherein the first spacing regions and the second spacing regions are filled with the first overcoat layer, a third refractive index of the first overcoat layer is less than a first refractive index of the first isolation layer, and is less than a second refractive index of the second isolation layer; and
forming a subsequent manufacturing process of the display substrate.

19. The method according to claim 18, wherein before forming the first isolation layer on the buffer layer, the method further comprises:
depositing a third metal layer on the buffer layer, and performing trace etching on the third metal layer to obtain a patterned first metal layer,
wherein a trace width of the third metal layer is greater than a trace width of the first metal layer, and is greater than a trace width of the second metal layer.

20. A display screen, comprising: a power supply assembly, and a display substrate, wherein the display substrate is provided with a first-type pixel region and a second-type pixel region, the first-type pixel region being a normal pixel region, and the second-type pixel region being a privacy pixel region; and the display substrate comprises:
a substrate, a pixel part, and a touch part, wherein the pixel part is disposed on the substrate, and the touch part is disposed on a side of the pixel part distal to the substrate;
wherein the touch part comprises a first isolation layer, a second isolation layer, and a first overcoat layer, and the second isolation layer is disposed on a side of the first isolation layer distal to the substrate;
in the second-type pixel region, the first isolation layer is provided with a plurality of first spacing regions, the second isolation layer is provided with a plurality of second spacing regions, and the first spacing regions and the second spacing regions correspond to an orthographic projection of a pixel light-emitting region of the pixel part on the substrate; and
the first overcoat layer is disposed on a side of the second isolation layer distal to the substrate, and the first spacing regions and the second spacing regions are filled with the first overcoat layer;
wherein a third refractive index of the first overcoat layer is less than a first refractive index of the first isolation layer, and is less than a second refractive index of the second isolation layer; and
the power supply assembly is connected to the display substrate and is configured to supply power to the display substrate.
